(19) United States
(12) Patent Application Publication
(10) Pub. No.: US 2012/0126197 A1
(43) Pub. Date: May 24, 2012

(54) Structure and process of basic complementary logic gate made by junctionless transistors

(75) Inventors: Steve S. Chung, Hsinchu City (TW); E. R. Hsieh, Hsinchu City (TW)

(73) Assignee: National Chiao Tung University, Hsinchu City (TW)

(21) Appl. No.: 13/064,168

(22) Filed: Mar. 9, 2011

(30) Foreign Application Priority Data
Nov. 19, 2010 (TW) 099140070

(51) Int. Cl. H01L 27/092; H01L 21/782; H01L 21/8238

(52) U.S. Cl. 257/9; 438/199; 438/154; 257/E27.062; 257/E21.632; 257/E21.7

(57) ABSTRACT

The present invention discloses a structure and process of basic complementary logic gate made by junctionless transistors. Junctionless N-channel transistor(s) and junctionless P-channel transistor(s) are formed on a semiconductor wafer, a conducting contact structure is used to connect the transistors to form a basic complementary logic gate(s) such as inverter, NAND, NOR, etc.

### BACKGROUND OF THE INVENTION

1. Field of the Invention

The present invention relates to a structure and process of basic complementary logic gate made by junctionless transistors, and more particularly to a novel logic design of elementary device to replace the logic device such as inverters, NANDs, and NORs made by CMOS device.

2. Description of Relative Prior Art

Junctionless transistors is different from the traditional field effect transistor made by gate, source junction and drain junction. Junctionless transistors has gate only but without traditional diffused pn junctions for source and drain, thus it is more simple to control the effective length of the channel, the process is relatively simple and contribute to decrease the size of the field effect transistors.

Recently, the technology of junctionless transistors still in device level, but in circuit level, it is still in development stage.

U.S. Pat. No. 7,534,675 B2 to Sarunya Bangsaruntip et al. teaches techniques for fabricating nanowire field effect transistors. A nanowire is deposited on the SOI layer so as to cover a portion of the nanowire that form a channel region, on the nanowire, a gate and metal or silicide is formed on the nanowire, they are limited on field effect transistors, and has not touched the circuit design. U.S. Pat. No. 7,795,677 B2 to Sarunya Bangsaruntip et al. teaches an improved process and still not yet touched the circuit design.

It is desirable to have transistor circuits and logic devices that make use of the junctionless field effect transistors

### OBJECTS OF THE INVENTION

It is therefore an object of the invention to provide a basic complementary logic gate made by junctionless transistors to fablicate smaller area, faster and more easy to process basic complementary logic gate devices

It is another object of the invention to provide a basic complementary logic gate made by junctionless transistors to reduce power consumption.

It is a further object of the invention to provide a basic complementary logic gate made by junctionless transistors to apply in VLSI 20 nm dot and more advanced technology.

### DISCLOSURE OF THE INVENTION

A first aspect of the present invention teaches a structure of basic complementary logic gate made by junctionless transistors, including: Forming N-channel and P-channel junctionless field effect transistors in immediate neighbors on a semiconductor wafer; A conducting contact structure is used to connect the transistors to form basic complementary logic gate(s).

A second aspect of the present invention teaches a processing method of basic complementary logic gate made by junctionless transistors, including inverters, NAND gates, NOR gates, that is: Forming N-doped and P-doped channel areas for field effect transistors on a semiconductor wafer, where the semiconductor wafer is group material wafer, silicon wafer or germanium wafer; Then depositing a layer of gate insulator on the semiconductor wafer; Forming a conducting layer on the gate insulator; Forming N-channel and P-channel junctionless field effect transistors in immediate neighbors by lithography and etching, the conducting contact structure is metal semiconductor alloy, poly crystalline semiconductor or metal; Forming N⁺⁺ doped on the N-doped area and P⁺⁺ doped on the P-doped area excluding the gate area; Forming basic complementary logic gate by forming conducting contact structure between transistors. Where the N-channel and P-channel junctionless field effect transistor is nanowire channel field effecy transistor, nanowire on SOI channel field effecy transistor.

### BRIEF DESCRIPTION OF THE DRAWING

FIG. 1 shows a sectional view of an inverter made by junctionless transistors.

FIG. 2(A) shows a plan view of an inverter made by nanowiwe channel junctionless field effect transistor.

FIG. 2(B) shows the sectional view of the gate.

FIG. 3 shows a sectional view of an inverter made by SOI (or UBTSOI) junctionless field effect transistor.

FIG. 4(A) shows a plan view of an inverter made by nanowiwe channel junctionless field effect transistor.

FIG. 4(B) shows the sectional view of the double gate.

FIG. 5(A) shows a plan view of an inverter made by nanowiwe channel junctionless field effect transistor.

FIG. 5(B) shows the sectional view of the triple gate.

FIG. 6 shows a perspective view of a coplemental logic gate made by two N-channel, two P channel junctionless field effect transistors

### DETAIL DESCRIPTION OF THE PRESENT INVENTION

The foregoing and other advantages of the invention will be more fully understood with reference to the description of the best embodiment and the drawing as the following description.

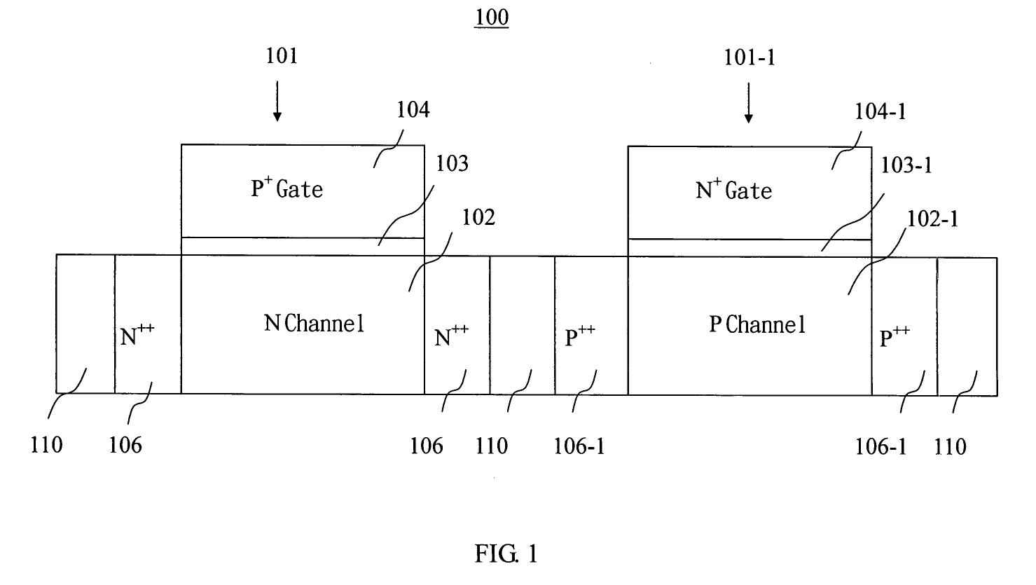

Please refer to FIG. 1, FIG. 1 shows a sectional view of an inverter made by junctionless field effect transistor, N-channel field effect transistor 101 and P-channel junctionless field effect transistors 101-1 in immediate neighbors, N-channel field effect transistor 101 has N-channel 102, gate insulator 103, P⁺ gate conductor 104 and N⁺⁺ doping area 106 out side the gate; P-channel junctionless field effect transistors 101-1 has P-channel 102-1, gate insulator 103-1, N⁺ gate conductor 104-1 and P⁺⁺ doping area 106-1 out side the gate. The N-channel and P-channel field effect transistors are connected by conducting contact structure 110 to form an inverter logic gate.

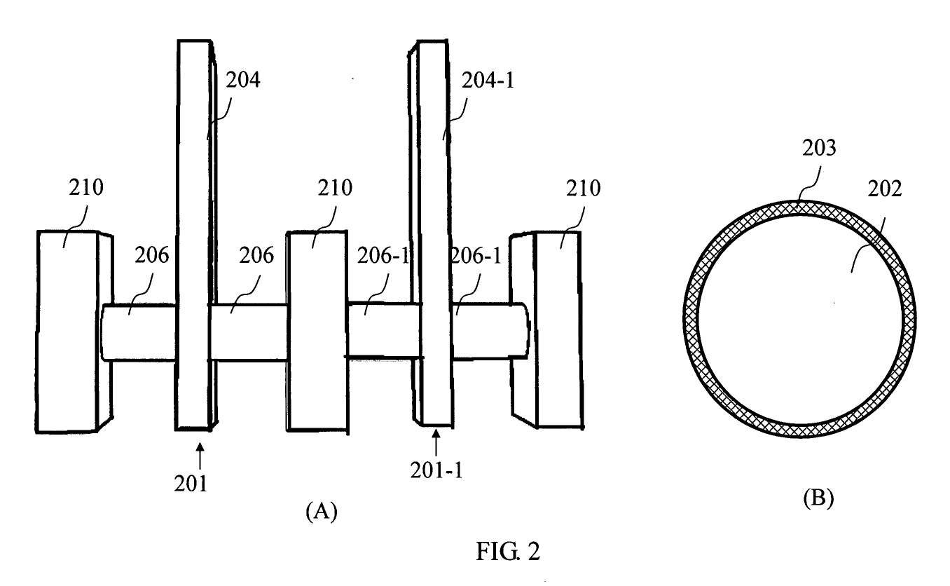

Please refer to FIG. 2, FIG. 2(A) shows a plan view of an inverter made by nanowiwe channel junctionless field effect transistor. FIG. 2(B) shows the sectional view of the gate. Nanowiwe N channel field effect transistor 201 has nanowiwe N channel 202 (see FIG. 2(B)), gate insulator 203, P⁺ gate conductor 204 and N⁺⁺ doping area 206 out side the gate; Nanowiwe P channel field effect transistor 201-1 has nanowiwe P channel 202-1, gate insulator 203-1, N⁺ gate conductor 204-1 and P⁺⁺ doping area 206-1 out side the gate. The N-channel and P-channel field effect transistors are connected by conducting contact structure 210 to form an inverter logic gate.

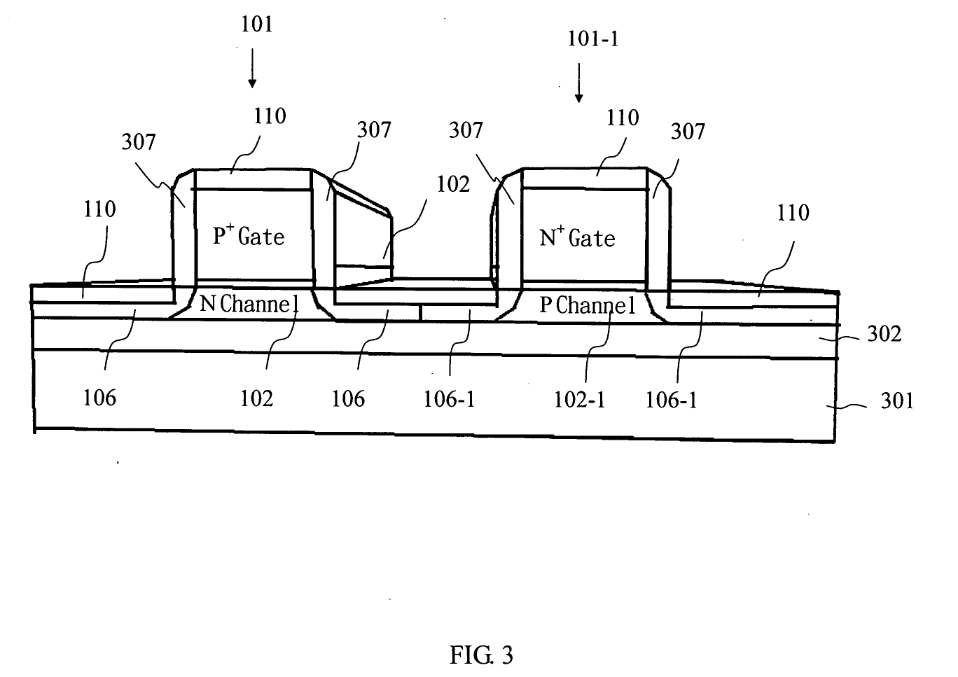

Please refer to FIG. 3, FIG. 3 shows a sectional view of an inverter made by SOI (or UBTSOI) junctionless field effect transistor. On SOI wafer 301, there is insulator layer 302. Junctionless N-channel field effect transistor 101 and P-channel junctionless field effect transistors 101-1 in immediate neighbors are formed on insulator layer 302. N-channel field effect transistor 101 and P-channel junctionless field effect transistors 101-1 in immediate neighbors, N-channel field effect transistor 101 has N-channel 102, gate insulator 103, P⁺ gate conductor 104 and N⁺⁺ doping area 106 out side the gate; P-channel junctionless field effect transistors 101-1 has P-channel 102-1, gate insulator 103-1, N⁺ gate conductor 104-1 and P⁺⁺ doping area 106-1 out side the gate. There is insulator side wall 307 on the latreral of the gate, conducting contact structure 110 on the gate. The N-channel and P-channel field effect transistors are connected by conducting contact structure 110 to form an inverter logic gate.

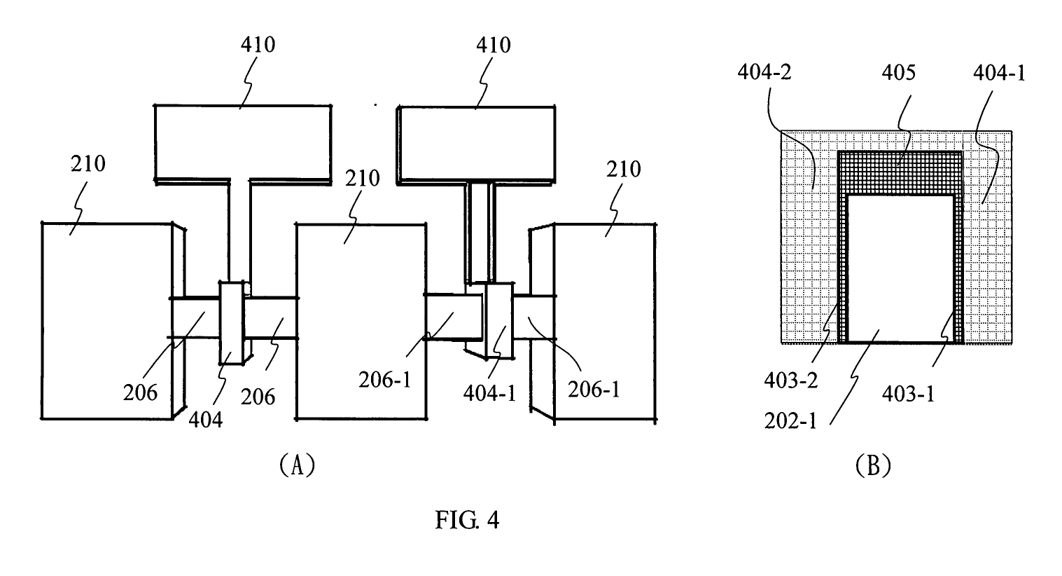

Please refer to FIG. 4, FIG. 4(A) shows a plan view of an inverter made by nanowiwe channel junctionless field effect transistor. FIG. 4(B) shows the sectional view of the double gate. N channel 202, P channel 202-1, P⁺ gate conductor 204 and conducting contact structure 410 on both sides are the same as FIG. 2, and the gate has conducting contact structure 410, but the gate of the P channel field effect transistor (see FIG. 4(B)) besides the N⁺ gate conductor 404-1, gate insulator 403-1 on the top, there is also N⁺ gate conductor 404-2, gate insulator 403-2 under the bottom, the thick insulator 405 can not form a gate.

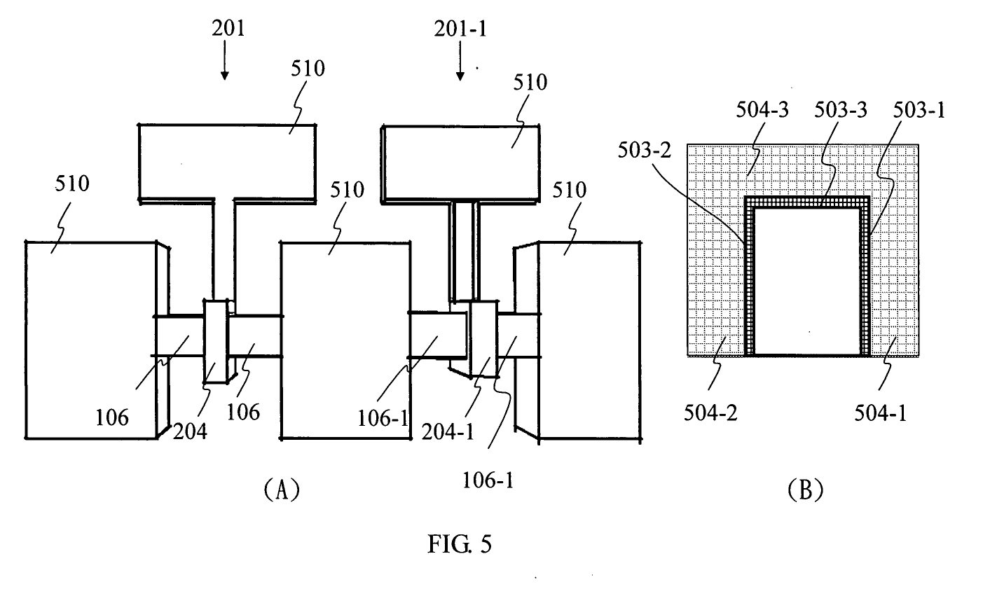

Please refer to FIG. 5, FIG. 5(A) shows a plan view of an inverter made by nanowiwe channel junctionless field effect transistor. FIG. 5(B) shows the sectional view of the triple gate. N channel 202, P channel 202-1 and conducting contact structure 510 on both sides are the same as FIG. 4, and the gate has conducting contact structure 510, but the gate of the P channel field effect transistor (see FIG. 4(B)) besides the N⁺ gate conductor 504-1, gate insulator 503-1 on the top, N⁺ gate conductor 504-2, gate insulator 503-3 under the bottom, there is also N⁺ gate conductor 404-3, gate insulator 403-3 on one side to form a triple gate.

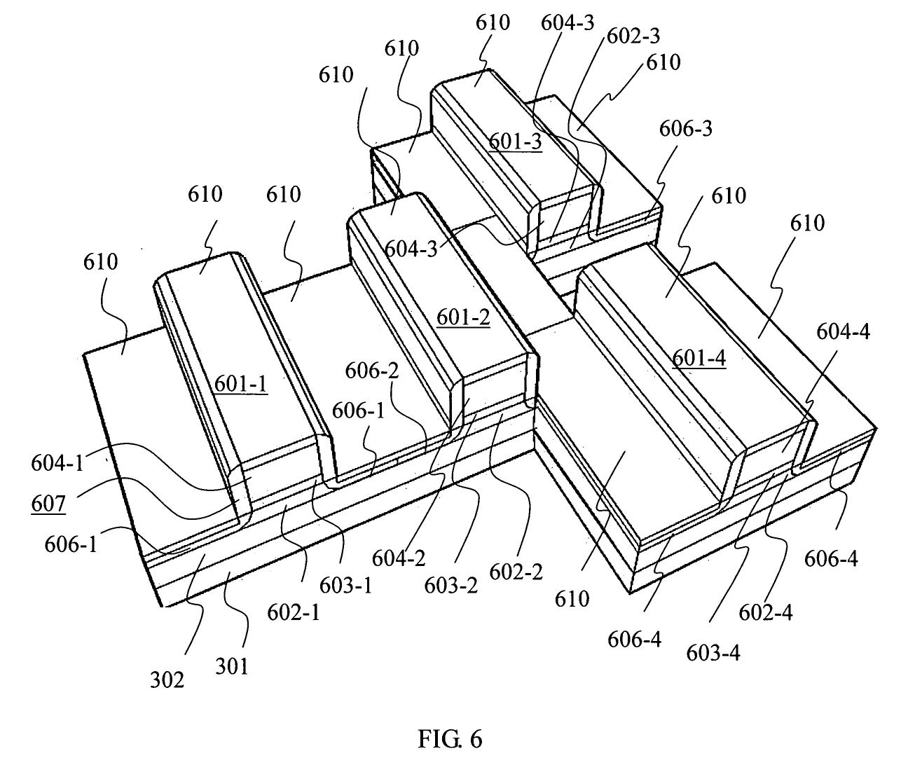

Please refer to FIG. 6, FIG. 6 shows a perspective view of a coplemental logic gate made by two N-channel, two P channel junctionless field effect transistors. On SOI wafer 602, there is insulator layer 603. Junctionless N-channel field effect transistor 601-1, 601-2 and P-channel junctionless field effect transistors 601-3, 601-4 in immediate neighbors are formed on the semiconductor layer of the insulator layer 602. N-channel field effect transistor 601-1, 601-2 has N-channel 602-1, 602-2, gate insulator 603-1, 03-2, P⁺ gate conductor 604-1, 604-2, and N⁺⁺ doping area 606-1, 606-2 out side the gate, respectively; P-channel junctionless field effect transistors 601-3, 601-4 has P-channel 602-3, 602-4, gate insulator 603-3, 603-4, N⁺ gate conductor 604-3, 604-4, and P⁺⁺ doping area 606-3, 606-4 out side the gate, respectively. There is insulator side wall 307 on the lateral of the gate and conducting contact structure 610 on the gate. The N-channel and P-channel field effect transistors are connected by conducting contact structure 610 to form a coplemental logic gate.

Although specific embodiments of the invention have been disclosed, it will be understood by those having skill in the art that minor changes can be made to the form and details of the specific embodiments disclosed herein, without departing from the spirit and the scope of the invention. The embodiments presented above are for purposes of example only and are not to be taken to limit the scope of the appended claims.

What is claimed is:

1. A structure of basic complementary logic gate made by junctionless transistors, comprising:
forming N-channel and P-channel junctionless field effect transistors in immediate neighbors on a semiconductor wafer;
a conducting contact structure is used to connect said transistors to form basic complementary logic gate(s).

2. A processing method of basic complementary logic gate made by junctionless transistors, including inverters, NAND gates, NOR gates, comprising:
forming N-doped and P-doped channel areas for field effect transistors on a semiconductor wafer;
depositing a layer of gate insulator on said semiconductor wafer;
forming a conducting layer on said gate insulator;
forming N-channel and P-channel junctionless field effect transistors in immediate neighbors by lithigraphy and etching;
forming N⁺⁺doped on said N-doped area and P⁺⁺doped on said P-doped area excluding the gate area;
forming basic complementary logic gate by forming conducting contact structure between transistors.

3. A structure or processing method as claimed in claim 1 or 2, wherein said semiconductor wafer is group III-V material wafer.

4. A structure or processing method as claimed in claim 1 or 2, wherein said semiconductor wafer is silicon wafer.

5. A structure or processing method as claimed in claim 1 or 2, wherein said semiconductor wafer is germanium wafer.

6. A structure or processing method as claimed in claim 1 or 2, wherein said N-channel and P-channel junctionless field effect transistor is nanowire channel fieldeffecy transistor.

7. A structure or processing method as claimed in claim 1 or 2, wherein said N-channel and P-channel junctionless field effect transistor is nanowire on SOI channel fieldeffecy transistor.

8. A structure or processing method as claimed in claim 1 or 2, wherein said conducting contact structure is metal semiconductor alloy.

9. A structure or processing method as claimed in claim 1 or 2, wherein said conducting contact structure is poly crystalline semiconductor.

10. A structure or processing method as claimed in claim 1 or 2, wherein said conducting contact structure is metal.
